(19) United States
(12) Patent Application Publication
(10) Pub. No.: US 2025/0337359 A1
(43) Pub. Date: Oct. 30, 2025

(54) VOLTAGE-CONTROLLED OSCILLATOR (LC VCO) AND METHOD OF OPERATION THEREOF

(71) Applicant: INDIAN INSTITUTE OF TECHNOLOGY ROPAR, Rupnagar (IN)

(72) Inventors: Mahendra SAKARE, Rupnagar (IN); Zahid Rashid SHEIKH, Rupnagar (IN); Rajasekhar NAGULAPALLI, Oxford (GB); Hitesh SHRIMALI, Mandi (IN)

(73) Assignee: INDIAN INSTITUTE OF TECHNOLOGY ROPAR, Rupnagar (IN)

(21) Appl. No.: 18/828,782

(22) Filed: Sep. 9, 2024

(30) Foreign Application Priority Data
Apr. 25, 2024 (IN) 202411032951

(51) Int. Cl. H03B 5/12

(52) U.S. Cl. CPC H03B 5/1209; H03B 5/1228; H03B 2200/009

(57) ABSTRACT

A dual tank LC-tuned Voltage Controller Oscillator (LC VCO) comprising a differential pair of cross-coupled transistors (M₁, M₂, M₃, M₄) produces a negative impedance by keeping a lower drain swing and a sufficient gate swing. The gate terminals of first and second transistors M₁, M₂ and third and fourth transistors M₃, M₄ are separated through a series of two inductors L₁, L₂ and two cross-coupled capacitors are connected between the drain and gate terminals of cross-coupled transistors to attenuate the output swing. The VCO tank further comprises two R2R Digital to Analog Converters (DAC) to bias both NMOS and PMOS cross-coupled pairs of transistors, to produce a common mode noise.

### CROSS-REFERENCE TO RELATED APPLICATIONS AND PRIORITY

The present application claim priority from Indian Patent Application No.: 202411032951 filed On: 25 Apr. 2024.

### TECHNICAL FIELD

The present subject matter described herein, in general, relates to very large-scale integration (VLSI) of radio frequency IC design. Particularly, the present subject matter relates to a LC-tuned voltage controller oscillator (VCO) to improve the phase noise performance.

### BACKGROUND OF THE INVENTION

Conventional VCO is based on a CMOS cross-coupled pair. M₁ and M₂ form the differential pair, and their gates and drain were cross-coupled. This cross-coupling produces a negative resistance to compensate for the tank loss. The negative resistance can be expressed as follows (where gₘ₁ and gm₂ represent NMOS and PMOS trans-conductance).

$${R}_{neg} = \frac{- 1}{{g}_{m 1} + {g}_{m 2}} \qquad ( 1 )$$

Where, L_{T}, C_{T} forms the parallel tank for producing frequency-stable oscillations. The frequency and parallel resistance can be expressed as follows.

$${W}_{osc} = \frac{1}{\sqrt{{L}_{T} {C}_{T}}} \qquad ( 2 )$$

$${R}_{eq} = {QL}_{T} {W}_{osc}$$

If the parallel loss component is greater than the negative resistance produced by the cross-coupled pair, then the oscillator will produce sustainable oscillations. Further, to produce sustainable oscillations, either the bias current is increased which improves the gm, or the Quality factor (Q) of the inductor is improved which reduces the tank loss. The amplitude of the output (o/p) waveform depends on the tank resistance and bias current. The output oscillations are of sinusoidal waveforms and if the current is much more than required then the waveform will saturate, and a square wave will be produced. The phase noise of the VCO depends on the output amplitude, which will increase the amplitude. A larger swing will push the operating region of M₁, and M₂ transistors out of the saturation region. At the maximum peak point of the voltage, PMOS will move into the triode region, whereas at the minimum voltage, NMOS will move into the triode region. Triode region-based operation will be creating loading onto the tank and hence degrade the Quality factor of the tank.

The conventional VCO has very higher gate and drain swings. Therefore, the gate swing is very important rather than the drain swing.

Hence to overcome the aforesaid drawbacks a dual-tank voltage controller oscillator (VCO) is required.

### OBJECTS OF THE INVENTION

Main object of the present disclosure is to provide a dual tank LC-tuned voltage-controlled oscillator (LC VCO) circuit comprising cross-coupled PMOS and NMOS transistors, inductors (L_{T}, L₁), capacitor (C₁, C_{V}), and R2R Digital to Analog Converter (DAC) circuit to generate a lower drain swing and a larger gate swing.

Another object of the present disclosure is to provide the dual tank LC-tuned voltage-controlled oscillator (LC VCO) to provide the R2R DAC circuit to bias both the NMOS and PMOS cross-coupled differential pair transistors.

Yet another object of the present disclosure is to provide the dual tank LC-tuned voltage-controlled oscillator to improve the phase noise of the VCO by 3 dB without increasing the power consumption.

Another object of the present disclosure is to provide the dual tank LC-tuned voltage-controlled oscillator (LC VCO) to improve the figure of merit (FOM) by 2.3 dB.

### SUMMARY OF THE INVENTION

Before the present system is described, it is to be understood that this application is not limited to the particular machine, device, or system, as there can be multiple possible embodiments that are not expressly illustrated in the present disclosures. It is also to be understood that the terminology used in the description is for the purpose of describing the particular versions or embodiments only, and is not intended to limit the scope of the present application. This summary is provided to introduce aspects related to the dual-tank voltage controller oscillator (LCVCO), and the aspects are further elaborated below in the detailed description. This summary is not intended to identify essential features of the proposed subject matter nor is it intended for use in determining or limiting the scope of the proposed subject matter.

The present invention discloses a dual-tank LC-tuned voltage-controlled oscillator (LC VCO) comprises various interconnected components to achieve its functionality. At its core lies a negative impedance circuit consisting of two pairs of transistors: a lower pair comprising the first (M₁) and second (M₂) transistors, and an upper pair consisting of the third (M₃) and fourth (M₄) transistors. The drain terminal of the third transistor (M₃) is linked to that of the first transistor (M₁), while the drain terminal of the fourth transistor (M₄) is connected to the second transistor (M₂). Furthermore, to control the transistors' behaviour, the gate terminal of each transistor pair is coupled via a pair of serially connected inductors (L₁, L₂), ensuring interconnection between the first and second transistors as well as the third and fourth transistors. Additionally, the oscillator incorporates a swing extension circuit designed for AC coupling of each transistor pair. This arrangement involves cross coupling through individual capacitors (C₁, C₂, C₃, and C₄), contributing to the oscillation process. Meanwhile, the Voltage Controlled Oscillator (VCO) tank circuit (101) plays a crucial role, featuring an inductive element (L_{T}) and a pair of capacitive elements (C_{5T} and C_{6T}) linked across the drains of the lower pair of transistors and the drain terminals of the upper pair of transistors. This arrangement facilitates the generation of the oscillating signal. Moreover, a biasing circuit is integrated, consisting of two Digital-to-Analog Converters (DACs) denoted as D₁ and D₂. D₁ is applied to the center tap of the serially connected inductors (L₁, L2) positioned between the gate terminals of the first and second transistors (M₁, M₂), while D₂ is similarly applied between the gate terminals of the third and fourth transistors (M₃, M₄). This biasing mechanism ensures stable operation of the oscillator. The combined action of the swing extension circuit and the biasing circuit maintains the negative impedance circuit in the saturation region, optimizing its performance. Furthermore, the swing extension circuit induces a 180-degree phase shift in the generated outputs, V_{OP} and V_{ON}, of the VCO tank circuit (101). These outputs are directly connected to the drain terminals of the transistor pairs (M₁, M₂) and (M₃, M₄), respectively, completing the functionality of the LC VCO.

In an embodiment, the present invention discloses that the inductor (L₁) has a value of 100 Pico Henry (pH) and the inductor (L₂) has a value of 500 Pico Henry (pH), configured to achieve a frequency of 12 GHz; and wherein, the frequency is tuned with a design equation of f=(1)/(2\pi\sqrt(LC)).

In an embodiment, the present invention further elaborates on the capacitor connections: wherein capacitor C₂ couples the gate of the first transistor to the drain of the second transistor, capacitor C₁ couples the drain of the first transistor to the gate of the second transistor, capacitor C₄ couples the gate of the third transistor to the drain of the fourth transistor and, capacitor C₃ couples the drain of the third transistor to the gate of the fourth transistor.

In an embodiment, the present invention provides that the capacitors (C_{5T} and C_{6T}) values vary from 200 fF-500 fF.

In an embodiment, the present invention discloses that inductive element (L_{T}) of the VCO tank circuit (101) is connected in parallel to the pair of capacitive elements.

In yet another embodiment, the present invention discloses that the inductive element and capacitive elements are configured to determine the frequency and set the oscillation frequency of the VCO.

In still another embodiment, the present invention discloses that the upper pair of transistors is a cross-coupled PMOS transistor pair, while the lower pair is a cross-coupled NMOS transistor pair.

In still another embodiment, the present invention discloses that the cross-coupled capacitors C₁-C₄ are configured to attenuate the output swing of the negative impedance circuit.

In still another embodiment, the present invention discloses that the serially connected inductors (L₁, L₂) placed between the gate terminals of the NMOS and PMOS transistors ensure different swings for the gate and drain terminals of the transistors.

In still another embodiment, the present invention discloses a method for operating a dual-tank LC-tuned voltage-controlled oscillator (LC VCO) involves several steps. Firstly, it entails establishing a negative impedance circuit, which comprises two pairs of transistors: a lower pair consisting of first (M₁) and second (M₂) transistors, and an upper pair comprising third (M₃) and fourth (M₄) transistors. These pairs are interconnected by coupling the drain terminals of the third and fourth transistors to those of the first and second transistors, respectively. Additionally, the gate terminals of the first and third transistors are connected to those of the second and fourth transistors via pairs of serially connected inductors (L₁, L₂). Subsequently, a swing extension circuit is provided, which incorporates AC coupling of each transistor pair through individual capacitors (C₁, C₂, C₃, C₄). Alongside this, a Voltage Controlled Oscillator (VCO) tank circuit (101) is established, comprising an inductive element (L_{T}) and a pair of capacitive elements (C_{5T} and C_{6T}) connected across the drains of the lower pair of transistors and the drain terminals of the upper pair of transistors. Furthermore, a biasing circuit is introduced, involving the application of a first Digital-to-Analog Converter (DAC) (D₁) to the centre tap of the serially connected inductors (L₁, L₂) positioned between the gate terminals of the first and second transistors, and a second DAC (D₂) to the centre tap of the serially connected inductors (L₁, L₂) positioned between the gate terminals of the third and fourth transistors. The method then ensures the negative impedance circuit remains in the saturation region by utilizing the swing extension circuit and the biasing circuit. Finally, the VCO tank circuit (101) is employed to generate two outputs, V_{OP} and V_{ON}, with a 180-degree phase shift, wherein V_{OP} and V_{ON} are directly connected to the drain terminals of the transistors (M₁, M₂) and (M₃, M₄), respectively.

In still another embodiment, the present invention discloses that the required resolution of the required bias voltages to the negative impedance circuit (100, 101), the DAC can be used with its overall number of bits (N). For an oscillation with very low amplitude, 5 bits of DAC are sufficient enough for the proposed structure, however, N bits can be determined with the required resolution of the bias voltage. The DAC may be any suitable structure of current, voltage, and charge depending on the requirement. For the LC VCO structure, the resistive DAC generates DC Levels.

### BRIEF DESCRIPTION OF DRAWING

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1: illustrates the prior art consisting of a circuit diagram of the 3^{rd} order Integer-N phase-locked loop (PLL).

FIG. 2: illustrates the prior art consisting of conventional LC-tuned voltage-controlled oscillators (LC VCO) comprising transistors, inductor (L_{T}), and capacitor (C_{T}).

FIG. 3: illustrates the proposed LC-tuned voltage-controlled oscillators (LC VCO) circuit comprising cross-coupled transistors, inductors (L_{T}, L₁), capacitors (C₁, C_{V}), and R2R DAC circuit.

FIG. 4: illustrates the simulation response of voltage swings at the drain and gate terminals of the LC VCO tank.

FIG. 5: illustrates the simulation response of the phase noise between the proposed and conventional LC VCO tank.

The figures depict various embodiments of the present disclosure for purposes of illustration only. One skilled in the art will readily recognize from the following discussion that alternative embodiments of the structures illustrated herein may be employed without departing from the principles of the disclosure described herein.

### DETAILED DESCRIPTION OF THE INVENTION

Some embodiments of this disclosure, illustrating all its features, will now be discussed in detail. The words “comprising”, “having”, and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any devices and methods similar or equivalent to those described herein can be used in the practice or testing of embodiments of the present disclosure, the exemplary, devices and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

Following is a list of elements and reference numerals used to explain various embodiments of the present subject matter.

| Reference Numeral | Element Description |
|---|---|
| (LC VCO) | Dual tank LC-tuned voltage-controlled oscillator |
| 100 | Negative impedance circuit: Upper pair |
| 101 | Voltage controlled Oscillator (VCO) tank circuit |
| 102 | Negative impedance circuit: Lower pair |
| (M₁, M₂) | Cross-coupled NMOS transistors or First |
| | transistor and second transistor |
| (M₃, M₄) | Cross-coupled PMOS transistors or third |
| | transistor and fourth transistor |
| (L₁) & (L₂) | Serially connected Inductor |
| (C₁, C₂, C₃, C₄) | Cross coupled Capacitors |
| (L_{T}) | Inductor of the VCO tank |
| (C_{5T} and C_{6T}) | Capacitors of the VCO tank |
| (D₁, D₂) | R2R Digital-to-analog converters (DAC) |
| (V_{OP}) | Output (V_{OP}) |
| (V_{ON}) | Output (V_{ON}) |
| 400 | Voltage waveforms at the Drain and Gate terminal |
| 402 | Drain swing |
| 404 | Gate swing |
| 500 | Phase noise graph |
| 502 | Conventional phase noise graph |
| 504 | Phase noise graph of dual tank LC VCO circuit |

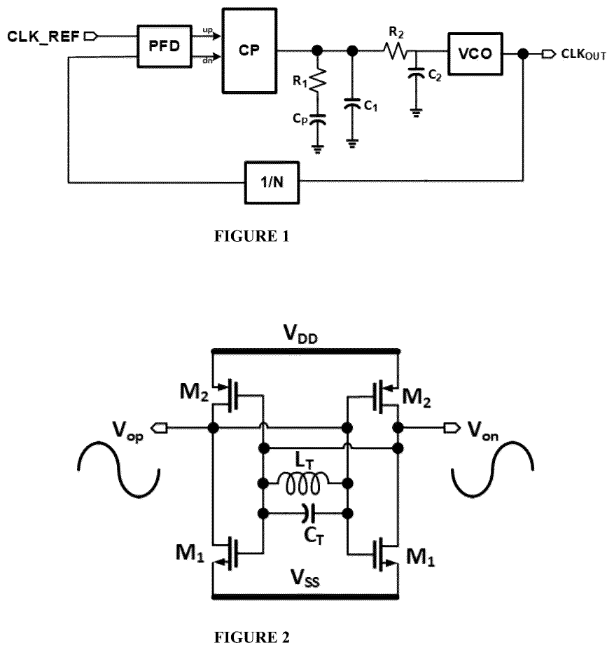

FIG. 1 illustrates a prior art showing a simplified diagram of a 3^{rd} order Integer-N phase-locked loop (PLL). The PLL circuit comprising a phase frequency detector (PFD) receives input from the reference clock (CLK_REF), a charge pump (CP), capacitors (C₁, C₂, C_{P}), resistors (R₁, R₂), a voltage-controlled oscillator, output clock (CLK__{OUT}), and a low pass filter within its loop.

Phase Frequency Detector (PFD)—Phase Frequency Detector is a component within a Phase-Locked Loop (PLL) system that compares the phase and frequency of two input signals and generates an output signal representing their phase difference. The Phase Frequency Detector typically has two input signals. Reference Signal—This is typically the input signal that the PLL is trying to lock onto or synchronize with. It could be an external clock signal or a reference oscillator signal. Feedback Signal—This is the output signal generated by the PLL's Voltage-Controlled Oscillator (VCO) or another element of the feedback loop. It represents the PLL's current output frequency and phase. Phase evaluation and locking a significant feature of a frequency-tracking circuit. The PFD analyses the output signal phase with the reference signal phase and generates a control signal proportional to the phase error.

Charge Pump (CP)—The charge pump converts the phase difference between the reference input signal and the feedback signal (usually from a Voltage-Controlled Oscillator or VCO) into a control voltage. It consists of a pair of switches and a capacitor. While the polarity of the current varies based on the value of the “UP” and “DOWN” signals, the current's amplitude never changes. The loop filter is a low-pass filter that smoothens the output of the charge pump, converting the pulsed output from the charge pump into a continuous control voltage.

Loop-Filter—The loop filters remove high-frequency components from the charge pump output, allowing only the DC component to pass through it. This DC voltage serves as the control voltage for the VCO, adjusting its frequency to minimize the phase difference between the reference and feedback signals. The low-pass filter removes high-frequency elements in the PFD output, enabling the DC value to adjust the voltage-controlled oscillator frequency (VCO). A loop filter consists of a passive RC network.

Voltage Controlled Oscillator (VCO)—Voltage-controlled oscillators are an essential part of the PLL architecture. A VCO's fundamental idea is to give a clock by following the Barkhausen criteria for oscillation. Barkhausen criteria say that the VCO's transfer function magnitude at the oscillation frequency is one while the phase is at −180 degrees. VCO's output frequency is linearly related to the input voltage applied. In LC-VCO, phase noise performance is good, but it takes a larger area to implement. LC VCO will be used for better phase noise performance.

Frequency divider—A frequency divider in the PLL is required for the multiple rations output frequency signals. The frequency divider gives the divided clock signal to be locked with the reference signals. This operation is done with the 1/N divider. The clock is divided by multiple factors to synchronize the reference clock signal.

FIG. 2 illustrates a prior art showing a simplified diagram of a conventional voltage controller oscillator (VCO). The VCO comprises a CMOS cross-coupled pair of transistors (M₁ and M₂). The transistors M₁ and M₂ form the differential pair, and the gates and drain of M₁ and M₂ transistors are cross-coupled. The cross-coupling of M₁ and M₂ transistors produces the negative resistance to compensate for the loss of VCO tank. The negative resistance is expressed as follows (where gₘ₁ and gm₂ represent NMOS and PMOS transconductance.

$${R}_{neg} = \frac{- 1}{{g}_{m 1} + {g}_{m 2}} \qquad ( 1 )$$

The VCO circuit further comprises the inductor (L_{T}) and capacitor (C_{T}) are connected parallelly to produce frequency-stable oscillations. The frequency and parallel resistance can be expressed as follows.

$${W}_{osc} = \frac{1}{\sqrt{{L}_{T} {C}_{T}}} \qquad ( 2 )$$

$${R}_{eq} = {QL}_{T} {W}_{osc}$$

Further, if the parallel loss component is greater than the negative resistance produced by the cross-coupled pair, then the oscillator will produce sustainable oscillations. To produce sustainable oscillations, either the VCO circuit is increasing the bias current by improving the gm or improving the Quality factor (Q) of the inductor to reduce the tank loss. The amplitude of the output (o/p) waveform depends on the VCO tank resistance and bias current. The output oscillations are of sinusoidal waveforms and if the current is much more than required then the waveform will saturate, and a square wave will be produced. The phase noise of the VCO depends on the output amplitude, which will increase the amplitude. A larger swing will push the operating region of M₁, and M₂ transistors out of the saturation region. At the maximum peak point of the voltage, PMOS will move into the triode region, whereas at the minimum voltage, NMOS will move into the triode region. Triode region-based operation will be creating loading onto the tank and hence degrade the Quality factor of the tank.

The circuit shown in FIG. 2 is a very simple and reliable architecture. The phase noise practice is to increase the signal swing to improve the as explained in Lesson's formula shown in (3).

$$L ( f ) = \frac{4 KTFR}{{V}_{rms}^{2}} {( \frac{{w}_{o}}{2 Q δ W} )}^{2} \qquad ( 3 )$$

In an embodiment, the high swing leads to degradation in the noise and supply sensitivity in this architecture because the devices will be pushed out of the saturation region and the tank inductor is shunted to the supply/ground. Therefore, the tank loses its reactive power to the ground. The present invention improves the VCO phase noise from this aspect.

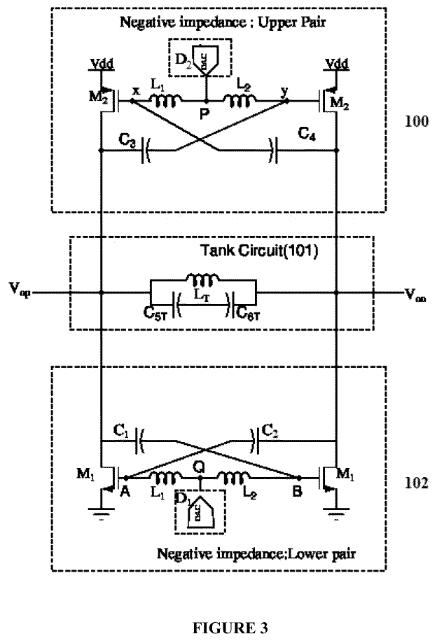

FIG. 3 illustrates a circuit diagram of the proposed LC tuned voltage controlled oscillator (LC VCO). FIG. 1 depicts a schematic diagram of the dual-tank LC-tuned voltage-controlled oscillator (LC VCO) according to an embodiment of the present invention. The LC VCO comprises a negative impedance circuit, a swing extension circuit, and a VCO tank (101) circuit. The negative impedance circuit includes a lower pair of transistors (M₁, M₂) and an upper pair of transistors (M₃, M₄). The source terminal of the third transistor (M₃) is coupled to the drain terminal of the first transistor (M₁), and the source terminal of the fourth transistor (M₄) is coupled to the drain terminal of the second transistor (M₂). The gate terminals of the first and third transistors (M₁, M₃) are coupled to the gate terminals of the second and fourth transistors (M₂, M₄), respectively, through pairs of serially connected inductors (L₁, L₂). This configuration facilitates cross coupling between the transistors, enabling stable oscillations.

The swing extension circuit comprises AC coupling of each transistor pair through individual capacitors (C₁, C₂, C₃, C₄). This circuitry aids in maintaining the negative impedance circuit in the saturation region, ensuring stable operation of the LC VCO. The VCO tank circuit (101) includes an inductive element (L_{T}) and a pair of capacitive elements (C_{5T} and C_{6T}) coupled across the drains of the lower pair of transistors and the drain terminals of the upper pair of transistors. These components determine the oscillation frequency of the LC VCO and generate two output signals, V_{OP} and V_{ON}, with a 180-degree phase shift. The V_{OP} and V_{ON} signals are directly connected to the drain terminals of the transistors M₁, M₃, and M₂, M₄, respectively.

In one embodiment, the inductor (L₁) has a value of 100 pico farads (pF), and the inductor (L_{T}) has a value of 500 pF. Additionally, the capacitors C₁, C₂, C₃, and C₄ are configured to facilitate cross-coupling between the transistors, attenuate output swing, and reduce common-mode noise.

Furthermore, in certain embodiments, the LC VCO may include digital-to-analog converters (DACs) (D₁, D₂) configured to bias the transistors, thereby reducing common-mode noise in the VCO tank. These DACs (D₁, D₂) can be applied to the centre taps of the serially connected inductors (L₁, L₂) to provide precise biasing control.

In an embodiment, the required resolution of the required bias voltages to the negative impedance circuit (100, 101), the DAC can be used with its overall number of bits (N). For an oscillation with very low amplitude, 5 bits of DAC are sufficient enough for the proposed structure, however, N bits can be determined with the required resolution of the bias voltage. The DAC may be any suitable structure of current, voltage, and charge depending on the requirement. For the LC VCO structure, the resistive DAC generates DC Levels.

The output terminals are directly connected to the drain terminals of the cross-coupled transistors of the VCO. The output swing is being attenuated by the capacitive divider formed by C₁ and C_{gs} of the transistors as shown in equation (4).

$${V}_{x} = {V}_{on} \frac{{C}_{1}}{{C}_{1} + {c}_{gs}} \qquad ( 4 )$$

In an embodiment, due to the swing reduction at the terminal, the phase noise is improved because there is no Quality factor degradation over the signal swing. The DAC voltage affects the output swing. Therefore, the swing control doesn't require complicated capacitive bank tuning.

The main issue with the conventional VCO is the gate and drain swings are too high, however, the gate swing is very important but not the drain swing. The proposed LC VCO circuit (300) is having lower drain swing and a large gate swing (enough to steer the current).

The oscillator phase noise is improved by enhancing the loaded quality factor (Q) of the LC VCO tank (300). Inductor Q will increase with the frequency and varactor Q will decrease with the frequency, hence overall LC VCO tank Q will be dominated by the inductor at a lower frequency. This can be increased by the following techniques.
1. Redesigning the inductor with a single turn and a larger area
2. Increasing the VCO capacitors (C_{5T} and C_{6T}) width and decreasing the length
3. Using a very small inductor (L₁) such that small series resistance to achieve the largest Q.

In an embodiment, every wireless or wireline system requires a precise and accurate clock system to assist the timing. To mitigate the setup and hold timing violations, the jitter of the clock should be as low as possible. The jitter of the clock system is decided by the clock generation system. A frequency synthesizer or phase-locked loop (PLL) will generate the required high-frequency clock by using the accurate reference clock (from the Crystal oscillator). The phase noise of the PLL decides the jitter of the clocking system. The Voltage Controlled Oscillator (VCO) and better phase with lower power consumption dominate the phase.

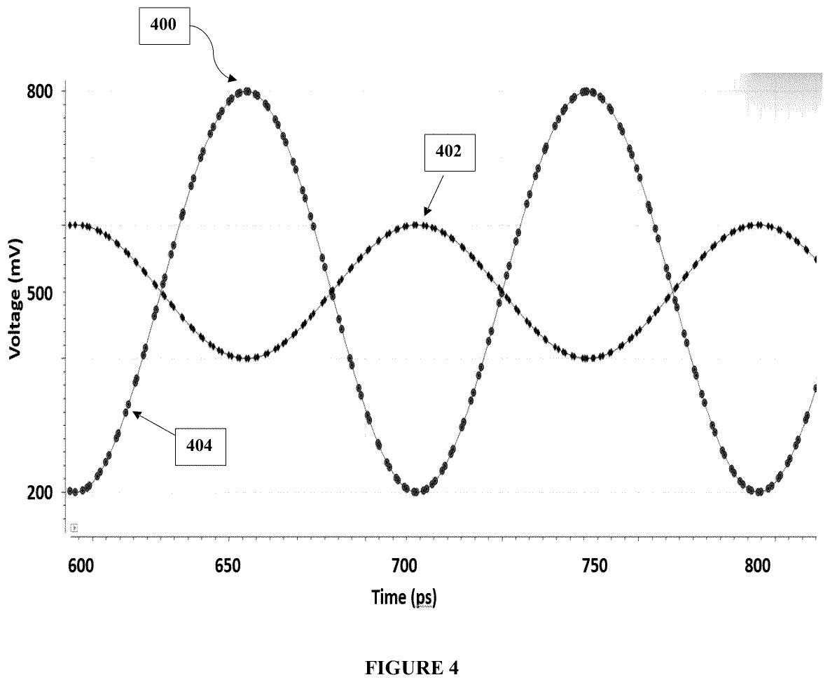

FIG. 4 illustrates the simulation graph (400) showing gate and drain voltage swings. LC VCO tank achieves the lower drain swing (402) and higher gate swing (404). The Drain swing (404) and gate swing (402) have a 180-degree phase shift with each other. The ratio of swing attenuation is (1:3) for a typical process corner at room temperature (27 deg).

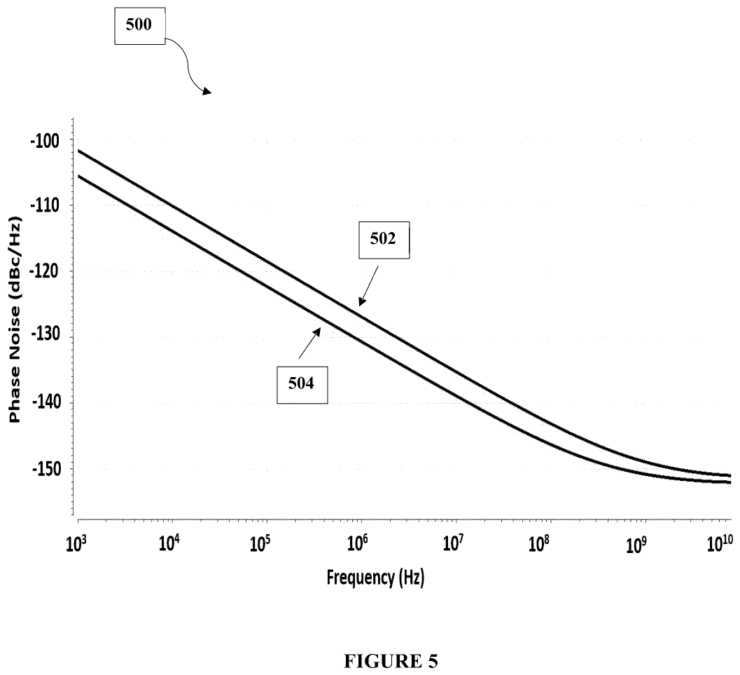

FIG. 5 illustrates the simulation graph (500) showing the comparison of the phase noise between the conventional (502) and proposed (LC VCO) circuit (505). The proposed LC VCO circuit (300) shows 3 dB improvement (−114 dBc/Hz) at 1 MHz frequency offset from the carrier frequency. The LC VCO circuit improves a phase jitter up to 19 femtoseconds (fs). The Phase jitter is calculated from the phase noise through the following integration expression.

$$Jitter = 1 / ( 2 \prod f\_ 0 ) \hat{} 2 √ ( \int \_l \hat{} h 2 S\_∅ ( f ) ) \qquad ( 5 )$$

In some embodiments, the dual-tank LC-tuned voltage-controlled oscillator (LC VCO) is proposed, to operate at 1 MHz frequency with an improved phase noise, phase jitter, figure of merit (FOM), and a quality factor.

In some embodiments, the value of the inductor L₁ is 100 picofarad (pF) and the inductor (L_{T}) is 500 picofarad (pF).

In some embodiments, the two outputs (Vₒₚ) and (Vₒₙ) of the VCO tank have a 180-degree phase shift with each other.

In some embodiments, the dual tank LC-tuned voltage-controlled oscillator (LC VCO) improves the phase noise of the VCO by 3 dB without increasing the power consumption.

In some embodiments, the dual tank LC-tuned voltage-controlled oscillator (LC VCO) improves the Figure of merit (FOM) by 2.3 dB.

In some embodiments, the dual tank LC-tuned voltage-controlled oscillator (LC VCO) improves phase jitter by 19 femtoseconds (fs).

In some embodiments, the dual tank LC-tuned voltage-controlled oscillator (LC VCO) improves the phase noise because there is no Quality factor degradation over the signal swing due to the swing reduction at the transistor terminal.

In some embodiments, the dual tank LC-tuned voltage-controlled oscillator (LC VCO) improves oscillator phase noise by enhancing the loaded quality factor (Q) of the tank.

In some embodiments, the dual tank LC-tuned voltage-controlled oscillator (LC VCO) redesigns the inductor with a single turn and a larger area.

In some embodiments, the dual tank LC-tuned voltage-controlled oscillator (LC VCO) increases the capacitor width and decreases the length of capacitor of the VCO tank.

In some embodiments, the dual tank LC-tuned voltage-controlled oscillator (LC VCO) provides a very small value inductor to achieve the largest Q.

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

Although implementations for the dual-tank LC-tuned voltage controller oscillator (LC VCO) have been described in language specific to structural features and/or methods, it is to be understood that the appended claims are not necessarily limited to the specific features described. Rather, the specific features are disclosed as examples of implementation for the dual-tank LC-tuned voltage controller oscillator (LC VCO).

1. A dual-tank LC-tuned voltage-controlled oscillator (LC VCO) comprising:
a negative impedance circuit comprising:
a lower pair of transistors comprising a first (M₁) and second (M₂) transistors;
an upper pair of transistors comprising a third (M₃) and fourth (M₄) transistors;
a drain terminal of the third transistor (M₃) coupled to a drain terminal of said first transistor (M₁), a drain terminal of said fourth transistor (M₄) coupled to a drain terminal of said second transistor (M₂);
a gate terminal of the first transistor (M₁) is coupled to a gate terminal of second transistor (M₂) through a pair of serially connected inductors (L₁, L₂) and a gate terminal of the third transistor (M₃) is coupled to a gate terminal of fourth transistor (M₄) through a pair of serially connected inductors (L₁, L₂); and
a swing extension circuit comprising:
AC coupling of each transistor pair, wherein each transistor pair is cross coupled through individual capacitors, C₁, C₂, C₃ and C₄;
a Voltage controlled Oscillator (VCO) tank circuit (101) comprising:
an inductive element (L_{T}) and a pair of capacitive element coupled (C_{5T}, C_{6T}) across the drains of the lower pair of transistors and the drain terminals of the upper pair of transistors;
a biasing circuit comprising:
a first DAC (D₁) is applied to a centre tap of the serially connected inductors (L₁, L₂) positioned between the gate terminal of the first transistor (M₁) and the gate terminal of second transistor (M₂); and
a second DAC (D₂) is applied to a centre tap of the serially connected inductors (L₁, L₂) positioned between the gate terminal of the third (M₃) and the gate terminal of the fourth transistor (M₄);
wherein the swing extension circuit and the biasing circuit maintain the negative impedance circuit in saturation region; and
wherein the swing extension circuit cause the VCO tank circuit to generate two output, V_{OP} and V_{ON}, which have a 180-degree phase shift with each other, wherein the V_{OP} and V_{ON} are directly connected to the drain terminals of the transistors (M₁, M₂) and (M₃, M₄), respectively.

2. The oscillator (LC VCO) as claimed in claim 1, wherein the inductor (L₁) has a value of 100 Pico Henry (pH) and the inductor (L₂) has a value of 500 Pico Henry (pH), configured to achieve a frequency of 12 GHz; and wherein, the frequency is tuned with a design equation of f=(1)/(2*pi*sqrt(LC))

3. The oscillator (LC VCO) as claimed in claim 1, wherein
the capacitor C₂ couples the gate of the first transistor to the drain of the second transistor,
the capacitor C₁ couples the drain of the first transistor to the gate of the second transistor,
the capacitor C₄ couples the gate of a third transistor to the drain of a fourth transistor, and
the capacitor C₃ couples the drain of the third transistor to the gate of the fourth transistor.

4. The oscillator (LC VCO) as claimed in claim 1, wherein the capacitors (C_{5T}, C_{6T}) values varies from 200 fF-500 fF.

5. The oscillator (LC VCO) as claimed in claim 1, wherein first DAC is configured to bias the lower pair of transistors and the second DAC is configured to bias the upper pair of transistors, to reduce common mode noise in the VCO tank.

6. The oscillator (LC VCO) as claimed in claim 1, wherein the inductive element (L_{T}) of the VCO tank circuit is connected in parallel to the pair of capacitive elements (C_{5T}, C_{6T}).

7. The oscillator (LC VCO) as claimed in claim 1, wherein the inductive element (L_{T}) and the capacitive elements (C_{5T}, C_{6T}) are configured to
a. determine the frequency of the VCO and
b. setting the oscillation frequency of the VCO

8. The oscillator (LC VCO) as claimed in claim 1, wherein said upper pair of transistors is a cross-coupled PMOS transistor pair, and the lower pair of transistors is a cross-coupled NMOS transistor pair.

9. The oscillator (LC VCO) as claimed in claim 1, wherein the cross coupled capacitors C₁-C₄, are configured to attenuate output swing of the negative impedance circuit.

10. The oscillator (LC VCO) as claimed in claim 1, wherein the serially connected inductors (L₁, L₂) placed in series between the gate terminals of the NMOS and PMOS transistors (M₁, M₂, M₃, M₄), ensures that the gate and drain terminals of the transistors experience different swings.

11. A method for operating a dual-tank LC-tuned voltage-controlled oscillator (LC VCO), comprising the steps of:
a. providing a negative impedance circuit comprising:
i. a lower pair of transistors comprising a first (M1) and second (M2) transistors;
ii. an upper pair of transistors comprising a third (M3) and fourth (M4) transistors;
iii. connecting a drain terminal of the third transistor (M3) to a drain terminal of the first transistor (M1), and connecting a drain terminal of the fourth transistor (M4) to a drain terminal of the second transistor (M2);
iv. coupling a gate terminal of the first transistor (M1) to a gate terminal of the second transistor (M2) through a pair of serially connected inductors (L1, L2), and coupling a gate terminal of the third transistor (M3) to a gate terminal of the fourth transistor (M4) through another pair of serially connected inductors (L1, L2);
b. providing a swing extension circuit comprising:
i. AC coupling of each transistor pair through individual capacitors (C1, C2, C3, C4);
c. providing a Voltage Controlled Oscillator (VCO) tank circuit (101) comprising:
i. an inductive element (LT) and a pair of capacitive elements (C_{5T}, C_{6T}) coupled across the drains of the lower pair of transistors and the drain terminals of the upper pair of transistors;
d. providing a biasing circuit comprising:
i. applying a first Digital-to-Analog Converter (DAC) (D1) to a center tap of the serially connected inductors (L1, L2) positioned between the gate terminal of the first transistor (M1) and the gate terminal of the second transistor (M2);
ii. applying a second Digital-to-Analog Converter (DAC) (D2) to a center tap of the serially connected inductors (L1, L2) positioned between the gate terminal of the third transistor (M3) and the gate terminal of the fourth transistor (M4);
e. maintaining the negative impedance circuit in the saturation region using the swing extension circuit and the biasing circuit;
f. generating two outputs, VOP and VON, from the VCO tank circuit with a 180-degree phase shift, wherein VOP and VON are directly connected to the drain terminals of the transistors (M1, M2) and (M3, M4), respectively.
